(19) United States
(12) Patent Application Publication
(10) Pub. No.: US 2009/0255582 A1
(43) Pub. Date: Oct. 15, 2009

(54) METHODS OF DRYING GLASS FOR PHOTOVOLTAIC APPLICATIONS

(75) Inventor: Masud Akhtar, Lawrenceville, NJ (US)

Correspondence Address: STERNE, KESSLER, GOLDSTEIN & FOX P.L.L.C., 1100 NEW YORK AVENUE, N.W., WASHINGTON, DC, 20005, US

(73) Assignee: EPV Solar, Inc., Robbinsville, NJ (US)

(21) Appl. No.: 12/422,004

(22) Filed: Apr. 10, 2009

Related U.S. Application Data
(60) Provisional application No. 61/007,541, filed on Apr. 10, 2008.

(51) Int. Cl. H01L 31/0203; H01L 31/18; C03C 15/00; C03C 3/00

(52) U.S. Cl. 136/259; 438/64; 65/30.1; 501/11; 257/E31.117

(57) ABSTRACT

This invention relates generally to methods of dehydrating glass substrates for use in photovoltaic modules, suitably by reacting moisture on the glass with organosilicon compounds. The invention also relates to methods of preparing thin film photovoltaic modules, which include dehydration of the glass substrates used in the manufacture of the photovoltaic modules.

### CROSS-REFERENCE TO RELATED APPLICATIONS

This application claims the benefit of U.S. Provisional Patent Application No. 61/007,541, which was converted to a provisional application on Oct. 21, 2008, from U.S. Nonprovisional application Ser. No. 12/100,799, filed Apr. 10, 2008, the disclosures of each of which are incorporated by reference herein in their entireties.

### BACKGROUND OF THE INVENTION

1. Field of the Invention

This invention relates generally to methods of dehydrating glass substrates for use in photovoltaic modules. The invention also relates to methods of preparing thin film photovoltaic modules, which include dehydration of the glass substrates used in the preparation of the photovoltaic modules.

2. Background Art

Large area glass substrates used in the manufacture of thin film photovoltaic modules or in optical instrumentation need to be carefully cleaned before their use. Glass cleaning methods employed for such applications typically include washing with a detergent solution, rinsing in water, then rinsing in an organic solvent like acetone or alcohol followed by drying by blowing air at the glass surface. For example, U.S. Pat. No. 6,374,640 discloses a glass cleaning method comprising immersing glass panes in an alkaline solution having a pH of more than 10, treating the glass panes with distilled water, treating the glass panes with an acidic medium (optionally containing surfactants) having a pH of less than 4, rinsing the glass panes again with distilled water and then drying the glass panes. Another general method for cleaning specialty glass substrates involves the washing of glass surfaces in refluxing freons or organic solvent vapors. However, none of these techniques are able to sufficiently remove adsorbed moisture from the surface of the glass.

The presence of moisture on glass panes that are used to make photovoltaic modules can ultimately lead to corrosion between adsorbed moisture and the photovoltaic module material (e.g., Si or other semiconductor material). Accordingly, there is a need for a glass drying technique, suitably for use within a temperature range of 100° to 400° Celsius, that can eliminate, or substantially reduce, adsorbed moisture in a photovoltaic module.

### BRIEF SUMMARY OF THE INVENTION

In embodiments, the present invention provides glass drying techniques, suitably for use within a temperature range of 100° to 400° Celsius, that eliminate, or substantially reduce, adsorbed moisture in a photovoltaic module.

In one embodiment, the present invention provides methods of drying a glass substrate for use in a photovoltaic module. A glass substrate is provided, heated, and a volatile organosilicon compound is introduced to the glass substrate. Water absorbed onto the glass substrate reacts with the compound to produce reaction products. The reaction products are then removed from the glass substrate.

In exemplary embodiments, a volatile hydrolizable organosilicon compound, such as a compound selected from the class of organosilicon compounds RₐSiX_{b}, where a and b are between 1 to 3 with a+b=4, R selected from CH₃, C₂H₅, and C₆H₅, and X is Cl or Br, is introduced. For example, (CH₃)₃SiX, or (C₂H₅)₃SiX, where X is Cl or Br, including trimethylchlorosilane, can utilized.

Suitably, the a volatile organosilicon compound is intruded at a pressure in the range of about −30 psi to about 30 psi. and the substrate is heated to a temperature in the range of about 100° Celsius to about 450° Celsius. Suitably, the heating occurs prior to the introduction of the volatile organosilicon compound.

In further embodiments, the present invention provides methods of preparing a photovoltaic module, and photovoltaic modules prepared by such methods. Suitably, a glass substrate is provided, heated, and a volatile organosilicon compound is introduced to the glass substrate. Water absorbed onto the glass substrate reacts with the compound to produce reaction products. The reaction products are then removed from the glass substrate. Exemplary volatile organosilicon compounds, as well as heating times, pressures, and temperatures, are disclosed herein.

A front contact electrode (e.g., tin oxide, indium-tin oxide, zinc oxide, or cadmium stannate) is then disposed on the glass substrate, and a photovoltaic module semiconductor is disposed on the front contact. A back contact electrode is then disposed on the photovoltaic module semiconductor. Suitably, the photovoltaic module is then encapsulated. The front contact electrode can comprise a multi-layer structure that includes a transparent metallic oxide layer and a dielectric layer. In other embodiments, the back contact electrode can comprise a multi-layer structure, including a doped material selected from the group consisting of, tin oxide, zinc oxide, indium-tin-oxide and cadmium stannate, and a metal such as aluminum, silver or alloys thereof.

Exemplary semiconductors for use in the practice of the present invention include un-doped, p-doped or n-type doped, hydrogenated microcrystalline silicon, hydrogenated amorphous silicon carbon, hydrogenated amorphous silicon germanium, CdTe or CIGS semiconductors. The semiconductors can be a single, tandem or triple junction photovoltaic module semiconductors. Suitably, the photovoltaic module is encapsulated in a polymer (e.g., ethylene vinyl acetate (EVA), polyvinyl acetate (PVA), PVB, Tedlar type plastic, Nuvasil type plastic, Tefzel type plastic, ultraviolet curable coatings and combinations thereof) and a moisture barrier, such as glass or a multiple layer structure. In additional embodiments, multiple laser scribings to interconnect the front contact electrode, the photovoltaic semiconductor and the back contact electrode are performed.

Further embodiments, features, and advantages of the invention, as well as the structure and operation of the various embodiments of the invention are described in detail below with reference to accompanying drawings.

### BRIEF DESCRIPTION OF THE DRAWINGS/FIGURES

The invention is described with reference to the accompanying drawings. In the drawings, like reference numbers indicate identical or functionally similar elements. The drawing in which an element first appears is indicated by the left-most digit in the corresponding reference number.

FIG. 1 shows a method of drying a glass substrate in accordance with one embodiment of the present invention.

FIG. 2 shows a method of preparing a photovoltaic module in accordance with one embodiment of the present invention.

FIG. 3 shows a cross-section of a photovoltaic module made by methods of the present invention.

### DETAILED DESCRIPTION OF THE INVENTION

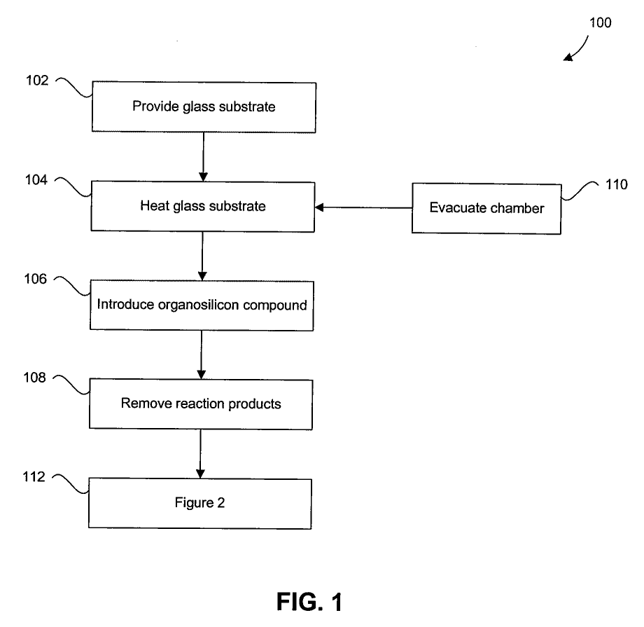

In exemplary embodiments, the present invention provides methods of drying glass substrates for use in a photovoltaic modules. The terms “drying” and “dehydrating” are used interchangeably throughout. For example, as shown in flowchart 100 of FIG. 1. In suitable embodiments, a glass substrate is provided in 102. The glass substrate is heated in 104, and in 106 of flowchart 100, a volatile organosilicon compound is introduced to the glass substrate. Water that is absorbed onto the glass substrate reacts with the compound to produce reaction products. These reaction products are then removed in 108 of flowchart 100. As used herein, “glass substrate” includes glass panels, glass panes, glass windows and the like, and can be translucent, transparent or opaque. Any suitable glass substrate can be utilized in the practice of the present invention, including by not limited to, soda lime glass, tempered glass, and the like.

Volatile organosilicon compounds for use in the practice of the present invention suitably include volatile hydrolizable organosilicon compounds. As used herein “volatile” means that the organosilicon compound that is contacted with the glass is in a gaseous state. Exemplary volatile hydrolizable organosilicon compounds for use in the practice of the present invention include, but are not limited to, compounds selected from the class of organosilicon compounds RₐSiX_{b}, where a and b are between 1 to 3, with the sum of a and b being equal to 4 (i.e., a+b=4). R is suitably selected from CH₃, C₂H₅, and C₆H₅, and X is Cl or Br. In exemplary embodiments, the organosilicon compound is (CH₃)₃SiX, or (C₂H₅)₃SiX, where X is Cl or Br. Suitably, the organosilicon compound is trimethylchlorosilane, (CH₃)₃SiCl.

The reaction of trimethylchlorosilane with moisture adsorbed onto the surface of glass is represented below as an exemplary reaction between water and an organosilicon compound. At a temperature of about 100° to about 400° Celsius the reaction proceeds as:

2(CH₃)₃SiCl+2H₂O→2(CH₃)₃SiOH+2HCl

(CH₃)₃SiOH→((CH₃)₃Si)₂O+H₂O

The over all reaction is:

2(CH₃)₃SiCl+H₂O→((CH₃)₃Si)₂O+2HCl

Thus the reaction of trimethylchlorosilane (CH₃)₃SiCl with water, H₂O, absorbed onto the glass surface produces two volatile reaction products hexamethyldisiloxane, ((CH₃)₃Si)₂O and hydrochloric acid, HCl. These reaction products exist in vapor/gaseous phase within the temperature range of about 100° to about 400° Celsius. Thus, they can be removed from the reaction site simply by evacuating a chamber containing the reactants, or by introducing an inert gas (such as Ar, N₂, He or Ne) to sweep away the reaction products. After removing the reaction products, moisture is eliminated from the surface, or substantially reduced on the surface (e.g., less than about 10% of the surface contains water molecules, suitably less than about 5%, less than about 1%, less than about 0.1%, less than about 0.01%, less than about 0.001%, less than about 0.0001%), thus producing a dried or dehydrated glass substrate. Suitably no water molecules are present on the surface of the glass.

In exemplary embodiments, the volatile organosilicon compound is introduced at a pressure in the range of about −30 psi to about 30 psi. For example, the glass substrate is placed in a chamber (e.g., an oven) and the volatile organosilicon compound is introduced until the pressure in the chamber reaches about 5 psi to about 30 psi, for example, about 10 psi to about 30 psi, about 15 psi to about 25 psi, or about 20 psi. Methods of introducing the volatile organosilicon compound to the glass surface are well known in the art, and include blowing, covering, immersing, or otherwise contacting the glass substrate with the compound. In exemplary embodiments, the compounds are introduced as pure organosilicon compounds, though in other embodiments, a carrier gas (e.g., an inert gas such as N₂, Ar, He, Ne, etc.) can be included with the compound.

Suitably, during the drying process, the glass substrate is heated to a temperature in the range of about 100° Celsius to about 450° Celsius, suitably about 200° Celsius to about 450° Celsius, about 250° Celsius to about 450° Celsius, about 300° Celsius to about 450° Celsius, or about 400° Celsius. In exemplary embodiments, the glass substrate is heated before the volatile organosilicon compound is introduced. In other embodiments, the volatile organosilicon compound is introduced, and then the glass substrate heated, while in still further embodiments, the volatile organosilicon compound can be introduced at the same time that the glass substrate is being heated.

In further embodiments, the methods of drying a glass substrate for use in a photovoltaic module, as shown in flowchart 100 of FIG. 1, comprise providing a glass substrate in 102, for example, in a chamber. As used herein, “chamber” refers to any suitable enclosure for the drying of glass panels, such as an oven, a hood, a vacuum chamber and the like. In 110, the chamber is evacuated to a pressure of about −40 psi to about −10 psi, suitably about −40 psi to about −20 psi, or about −30 psi during the drying process. “Evacuated” suitably comprises applying a vacuum to remove the gaseous environment surrounding the glass substrate. In 104 of flowchart 100, the glass substrate is heated, suitably to a temperature of about 300° C. to about 500° C., more suitably to a temperature of about 400° C. in the chamber (e.g., oven). A volatile organosilicon compound is then introduced to the glass substrate in 106. Suitably, the compound is introduced into the chamber until the pressure reaches about 10 psi to about 30 psi, suitably, about 20 psi. As noted above, water absorbed onto the glass substrate reacts with the compound to produce reaction products. In 108, the reaction products are then removed from the glass substrate, for example by evacuating the chamber, or by purging with an inert gas (e.g., N₂, Ar, He, Ne, etc.).

In suitable embodiments, the evacuating in 110 and the heating in 104 of flowchart 100 occur at the same time, and thus the chamber (e.g., oven) is simultaneously evacuated down to a pressure of about −20 psi, while the temperature is increased to above 400° C.

In further embodiments, the present invention provides glass substrates for use in photovoltaic modules prepared by the various methods described herein. Suitably, water has been eliminated, or substantially reduced, on the surface of the glass substrates (i.e., dried). As discussed herein, the use of a glass substrate from which water or moisture has been eliminated, or substantially reduced, helps to eliminate or substantially eliminate corrosion reactions that can occur between adsorbed moisture on the surface of the glass substrate and photovoltaic module material (e.g., semiconductor material).

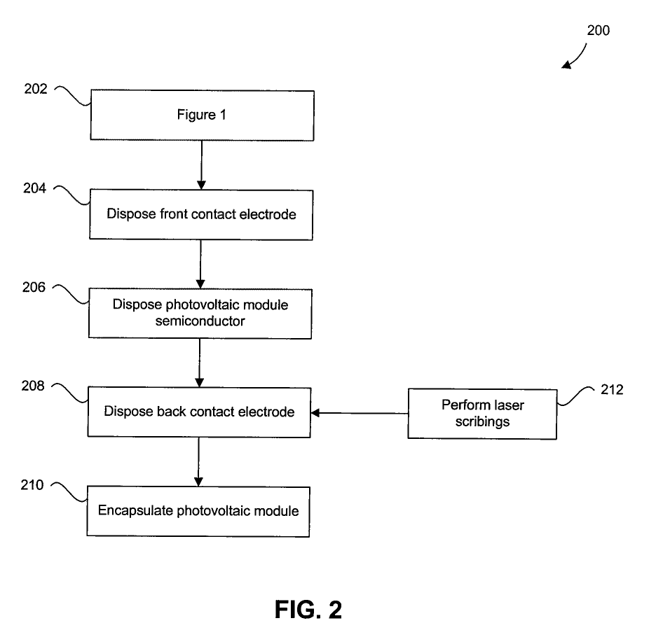

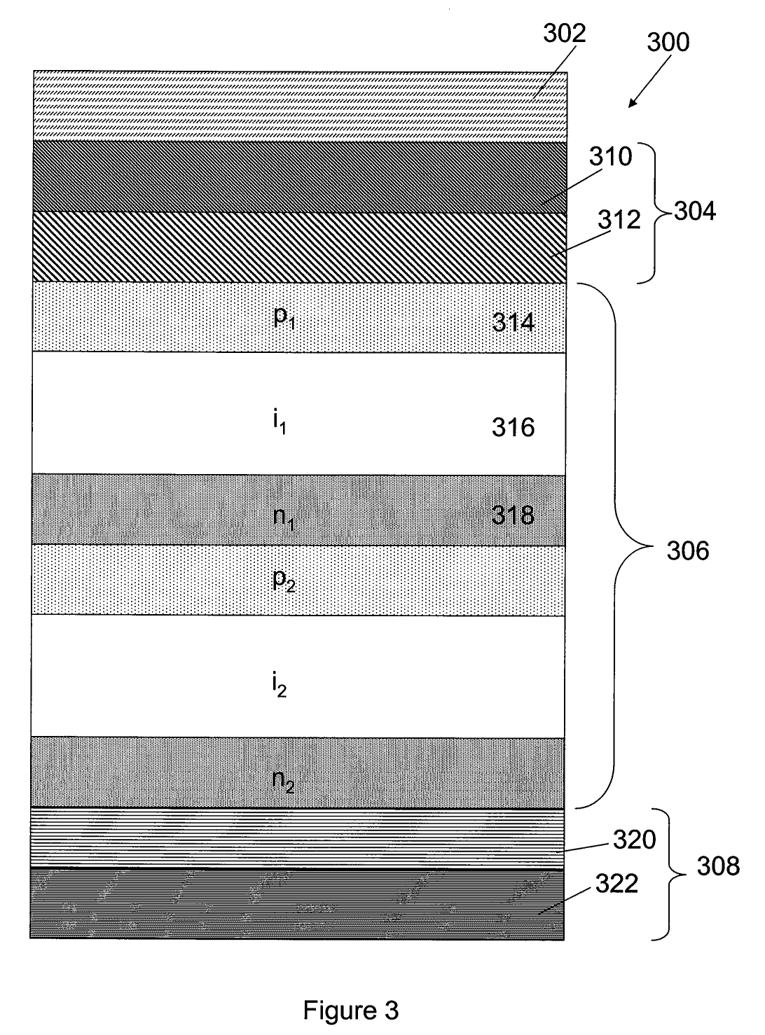

In further embodiments, the present invention provides methods of preparing photovoltaic modules (FIG. 2), as well as photovoltaic modules prepared by the various methods. FIG. 3 shows a cross-section of an exemplary photovoltaic module that can be produced using the methods of the present invention. Photovoltaic module 300 suitably comprises a glass substrate 302, a front contact electrode 304, a plurality of semiconductor layers 306, a back contact electrode 308 and an encapsulant (not shown). By eliminating, or substantially reducing the moisture that is absorbed onto the surface of a glass substrate 302 of a photovoltaic module 300, the lifetime of the thin film photovoltaic module can be prolonged. Removing moisture from the surface of the glass substrate eliminates, or substantially reduces, the corrosive reactions that occur between water and the photovoltaic module components, such as semiconductor materials, organic oxides, buffer layers, etc.

Methods of preparing photovoltaic modules in accordance with the present invention are shown in FIG. 2, with reference to the exemplary module shown in FIG. 3. The methods set forth in flowchart 200 of FIG. 2 suitably begin with the drying of a glass substrate, as shown in FIG. 1. Suitably, a glass substrate 302, is provided in 102. The glass substrate 302 is heated in 104, and then in 106, a volatile organosilicon compound is introduced to the glass substrate 302. As described herein, water absorbed onto the glass substrate reacts with the organosilicon compound to produce reaction products. These reaction products are then removed in 108 of flowchart 100. After drying of the glass substrate 302, the substrate is then ready for use in the methods of FIG. 2 (112 of flowchart 100).

The dried glass substrate 302 is suitably used 202 in the methods of flowchart 200 of FIG. 2. In 204 of flowchart 200, a front contact electrode 304 is disposed on glass substrate 302. Then, in 206 of flowchart 200, a photovoltaic module semiconductor 306 is disposed on front contact 304. A back contact electrode 308 is then disposed on photovoltaic module semiconductor 306 in 208 of flowchart 200. Finally, the photovoltaic module 300 is encapsulated in 210 of flowchart 200.

As used herein, the term “disposing” as it is used to describe the addition of various layers/elements of photovoltaic module 300 and includes any suitable method of applying the elements, such as, coating (including spin-coating), spraying, layering, dipping, deposition (including chemical vapor deposition, plasma enhanced chemical vapor deposition, vapor-liquid-solid deposition), painting, etc. The terms “dispose/disposition” and “deposit/deposition” are used interchangeably throughout.

The methods for drying glass substrate 302, as shown in flowchart 100, are described throughout, including exemplary volatile organosilicon compounds that can be used, as well as temperatures and pressures for the various stages of the methods. As noted herein, the glass substrate for use in the practice of the present invention can be opaque glass, translucent glass or transparent glass, including soda lime glass, tempered glass and the like. In suitable embodiments, glass substrate 302 is provided in a chamber, for example an oven. The chamber is then evacuated to a pressure of about −40 psi to about −10 psi, suitably about −30 psi. The glass substrate is then heated to a temperature of about 300° C. to about 500° C., suitably about 400° C. In exemplary embodiments, the evacuating of the chamber and the heating of the glass substrate are performed at the same time (or substantially the same time).

In exemplary photovoltaic modules, front contact electrode 304 comprises a material selected from the group consisting of, tin oxide, indium-tin oxide, zinc oxide, and cadmium stannate. Suitably, as shown in FIG. 3, front contact electrode 304 is a multi-layer structure. For example, front contact electrode 304 can comprise a transparent metallic oxide layer 312 (e.g., tin oxide, indium-tin oxide, zinc oxide or cadmium stannate) and a dielectric layer 310 (e.g., SiO₂). The use of a dielectric layer on the glass substrate limits contamination of the semiconductor layers by forming a coating on the glass.

Disposing of photovoltaic module layers 306 suitably comprise disposing semiconductor layers. For example, doped, hydrogenated amorphous silicon layers, hydrogenated amorphous silicon carbon layers, hydrogenated amorphous silicon germanium layers, CdTe or CIGS semiconductor layers can be disposed. In exemplary embodiments, the photovoltaic module semiconductor 306 comprises crystalline (including micro or nanocrystalline) and/or amorphous silicon. In exemplary embodiments, the photovoltaic module semiconductor 306 comprises three layers, e.g., a p-doped layer 314 (p₁), an intermediate, un-doped layer 316 (i₁) and an n-doped layer 318 (n₁). Such layers make up a single junction photovoltaic module semiconductor.

As shown in FIG. 3, in exemplary embodiments, a tandem or triple junction photovoltaic module semiconductor 306 can be produced. For example, as shown in FIG. 3, a second (or third, or fourth, etc.) set of p-doped, i-intrinsic and n-doped semiconductor layers can be disposed (e.g., p₂, i₂ and n₂), as shown in FIG. 3.

Disposing back contact electrode 308 in 208 of flowchart 200 suitably comprises disposing a multi-layer structure, 320 and 322, as shown in FIG. 3. For example, at least one of the layers of the multi-payer structure, suitably back contact 322, comprises a metal, such as aluminum silver or alloys thereof. Suitably, back contact electrode 308 comprises disposing a doped material 320 on photovoltaic semiconductor 306 prior to the disposing of back contact 322. In exemplary embodiments, doped material 320 is selected from the group consisting of tin oxide, zinc oxide, indium-tin-oxide and cadmium stannate.

In 210 of flowchart 200, the photovoltaic module is then encapsulated, suitably in a polymer and a moisture barrier (not shown in FIG. 3). In exemplary embodiments, the photovoltaic module is encapsulated in a polymer selected from the group consisting of ethylene vinyl acetate (EVA), polyvinyl acetate (PVA), polyvinyl butyral (PVB), polyvinyl fluoride (e.g., TEDLAR® type plastic, DuPont™), silicones (e.g., NUV-ASIL® type plastic, Henkel Corp.), ethylene-tetrafluoroethylene (e.g., TEFZEL® type plastic), ultraviolet curable coatings and combinations thereof. Moisture barriers that can be used in the methods of encapsulating suitably comprise glass or a multiple layer structure.

As shown in flowchart 200 of FIG. 2, in additional embodiments, the methods of preparing a photovoltaic module can further comprise performing laser scribing 212.

For example, three laser scribings can be used to interconnect the front contact electrode 304, the photovoltaic semiconductor 306 and the back contact electrode 308. Exemplary methods of laser scribing are described herein and well known in the art.

In exemplary embodiments, following the drying of the glass substrates in accordance with the various methods described herein, the glass substrates are then loaded onto a substrate carrier. The glass substrates are then preheated to a temperature in the range of about 100° C. to about 250° C., suitably about 140° C. to about 220° C. The photovoltaic module semiconductor layers 306 are then deposited, suitably from gaseous source materials. Exemplary gaseous phase source materials include, but are not limited to, silane, hydrogen, trimethylboron, methane, and phosphine. In exemplary embodiments, a front contact electrode 304 can be deposited prior to depositing the semiconductor layer, though in other embodiments, glass substrates comprising a pre-deposited front contact electrode can be provided. In exemplary embodiments, a first laser scribing step takes place to scribe the front contact electrode, including the oxide layer 312.

The deposition of the semiconductor layer suitably occurs in the temperature range of about 100° C. to about 250° C., suitably about 140° C. to about 220° C., to form a hydrogenated amorphous-silicon (a-Si) tandem junction cell, p₁i₁n₁/p₂i₂n₂, with the following layers: a-SiC:B (p1), a-Si (i1), a-Si:P (n1), a-SiC:B (p2), a-Si (i2) and a-Si:P (n2) (see, e.g., FIG. 3, 306). The glass substrates, with the semiconductor layers, are then cooled, and unloaded to a transport cart.

Back contact 308 is then deposited on the semiconductor layers 306. In one embodiment, ZnO (e.g., doped material 320) is sputter deposited onto the semiconductor layers 306. During a second laser scribing step, semiconductor (306) and ZnO (320) are patterned. A back contact 322, such as an aluminum back contact, is then deposited by sputtering. During a third scribing/patterning step, the aluminum (322) is scribed.

In exemplary embodiments, following patterning of the aluminum, the edge of the module 300 is encapsulated, and then the substrate is tested. Testing is suitably followed by foil bonding, EVA application, preheating and lamination. Wire/crimps are completed at an electrical station, suitably followed by the application of an adhesive at a mechanical station, adhesive curing and then cleaning.

It will be readily apparent to one of ordinary skill in the relevant arts that other suitable modifications and adaptations to the methods and applications described herein can be made without departing from the scope of the invention or any embodiment thereof. Having now described the present invention in detail, the same will be more clearly understood by reference to the following examples, which are included herewith for purposes of illustration only and are not intended to be limiting of the invention.

### Example 1

A batch of thin (about 2 mm thick) glass substrates with an approximate size of 2 feet by 2 feet are washed with a detergent solution, rinsed with de-ionized water and dried by blowing air at the glass surface. This batch of glass substrates is placed in a glass substrate holder with each substrate standing alone up-right and one inch apart from each other. The substrates are loaded into an oven. The oven is evacuated down to a negative pressure of about −30 psi while its temperature rises from ambient to about 400° Celsius. The oven is filled with a gaseous mixture of 20% (by pressure) of trimethylchlorosilane and 80% (by pressure) nitrogen gas up to a pressure of above one atmosphere, and closer to 20 psi. The loaded oven is maintained at this temperature and pressure for 2 hours. The oven heater is then turned off and the volatile contents of the oven are purged out with nitrogen gas, while the exhaust gases are being blown through a lime water scrubber. The oven is evacuated, filled with nitrogen gas up to a pressure of about 15 psi and opened when its temperature has reached ambient temperature. The glass substrates can then be used in the fabrication of photovoltaic modules or other electronic devices of choice.

### Example 2

A batch of thin (about 2 mm thick) glass substrates with an approximate size of 2 feet by 2 feet are washed with a detergent solution, rinsed with de-ionized water and dried by blowing air at the glass surface. This batch of glass substrates is placed in a glass substrate holder with each substrate standing alone up-right and one inch apart from each other. The substrates are loaded into an oven. The oven is evacuated down to a negative pressure of about −30 psi while its temperature rises from ambient to about 400° Celsius. The oven is filled with a gaseous mixture of 20% (by pressure) of a volatile hydrolizable organo silicon compound and 80% (by pressure) nitrogen gas up to a pressure of above one atmosphere and closer to 20 psi. The loaded oven is maintained at this temperature and pressure for 2 hours. The oven heater is then turned off and the volatile contents of the oven are purged out with nitrogen gas, while the exhaust gases are being blown through a lime water scrubber. The oven is evacuated, filled with nitrogen gas up to a pressure of about 15 psi and opened when its temperature has reached ambient temperature. The glass substrates can then be used in the fabrication of photovoltaic modules or other electronic devices of choice.

### Example 3

A batch of thin (about 2 mm thick) glass substrates with an approximate size of 2 feet by 2 feet are washed with a detergent solution, rinsed with de-ionized water and dried by blowing air at the glass surface. This batch of glass substrates is placed in a glass substrate holder with each substrate standing alone up-right and one inch apart from each other. The substrates are loaded into an oven. The oven is evacuated down to a negative pressure of about −30 psi while its temperature rises from ambient to about 400° Celsius. The oven is filled with a gaseous mixture of 20% (by pressure) of (CH₃)₃SiBr and 80% (by pressure) nitrogen gas up to a pressure of above one atmosphere and closer to about 20 psi. The loaded oven is maintained at this temperature and pressure for 2 hours. The oven heater is then turned off and the volatile contents of the oven are purged out with nitrogen gas, while the exhaust gases are being blown through a lime water scrubber. The oven is evacuated again, filled with nitrogen gas up to a pressure of about 15 psi and opened when its temperature has reached ambient temperature. The glass substrates can then be used in the fabrication of photovoltaic modules or other electronic devices of choice.

### Example 4

In this example, a photovoltaic module 300 is made with a soda lime float glass as the substrate 302. This type of substrate 302 provides support for the semiconductor 306. A batch of substrates 302 is placed in a glass substrate holder with each substrate 302 standing alone up-right and one inch apart from each other. The substrates 302 are loaded into an oven. The oven is evacuated down to a negative pressure of about −30 psi while its temperature rises from ambient to about 400° Celsius. The oven is filled with a gaseous mixture of 20% (by pressure) of trimethylchlorosilane and 80% (by pressure) nitrogen gas up to a pressure of above one atmosphere and closer to about 20 psi. The loaded oven is maintained at this temperature and pressure for 2 hours. The oven heater is then turned off and the volatile contents of the oven are purged out with nitrogen gas, while the exhaust gases are being blown through a lime water scrubber. The oven is evacuated, filled with nitrogen gas up to a pressure of about 15 psi and opened when its temperature has reached ambient temperature.

A thin film layer of SiO₂ 310 is deposited onto one side of each cleaned substrate 302. The SiO₂ keeps contaminants in the substrate 302 from migrating into the semiconductor layers 306. In addition, the SiO₂ layer 310 acts to smooth out and reduce structural peaks and valleys in the substrate 302. In this embodiment, the SiO₂ layer is a buffer or barrier layer. The SiO₂ is transparent to allow light photons to enter into the energy conversion part of the module 300. This layer can be deposited when the glass is being manufactured, or can be purchased as a component of the soda lime float glass, or can be deposited after cleaning and dehydration.

An SnO₂ layer 312 is deposited onto the SiO₂ film 310 to create a transparent conductive contact (transparent conductive oxide) for the photovoltaic module 300. This layer can be deposited when the glass is being manufactured (i.e., purchased as a component of the soda lime float glass), or after cleaning/dehydration and deposition of the SiO₂ layer. The SnO₂ layer has the characteristic of allowing about 70-90% of incident light to be transmitted into the energy conversion layers of the semiconductor, while also acting as an electrode to collect current flow. The SnO₂ has a conductivity of about 5 to 15 ohms/cm².

In suitable embodiments, the layers of the photovoltaic module 300 are interconnected with multiple laser scribing steps. High-powered industrial lasers are used to remove or ablate very thin strips of each of the thin-film materials (SiO₂ does not require this manufacturing step). Such laser scribing methods are well known in the art. In exemplary embodiments, three laser scribing steps are employed. The number of scribes and the distance between the ablation strips, or laser scribes, dictates the voltage and current characteristics. In this way, modules of varying voltage for different applications are produced. In successive thin film layers, the laser ablation process is used for laser patterning of those materials. This laser scribing process creates the lines that are seen on thin-film silicon photovoltaic devices.

A vacuum based plasma-enhanced chemical vapor thin-film deposition system is used to chemically vapor deposit hydrogenated amorphous silicon semiconductor layers 306. Three initial layers act as the P-I-N semiconductor junction (314, 316, 318). A second P-I-N junction is then deposited on the device to enhance the performance of the module. These semiconductor layers are deposited from gaseous source materials, including silane, hydrogen, trimethylboron, methane, and phosphine. The deposition occurs in the temperature range of about 140° to about 220° Celsius to form a hydrogenated amorphous-silicon tandem junction cell, p₁i₁n₁/p₂i₂n₂. When sunlight enters into this material, the light energy excites the silicon material, thereby creating a current flow. As previously mentioned, this material is patterned with the use of the laser material ablation system.

A thin layer of highly reflective ZnO (320) is deposited onto the second silicon P-I-N layer using a physical vapor sputter deposition process. The ZnO layer is highly reflective, so that any sunlight that passes through the semiconductor layers that is not converted to electricity is reflected back into the silicon layer for another opportunity for energy conversion. An aluminum layer (back contact 322) is suitably deposited on the ZnO layer. The conductive SnO₂ and succeeding ZnO 320 and aluminum layers 322 (back contact 308) act as the positive and negative electrodes. A pre-heat station is provided to pre-heat the glass/EVA/glass sandwich prior to the insertion of the sandwich into a vacuum laminator to complete the encapsulation.

### Example 5

In this example, a similar process as in Example 4 is followed. In this example, the front contact is a multi-layer structure of silicon dioxide 310 positioned upon and abutting against the inner surface of the glass substrate 302 and zinc oxide 312 deposited by low pressure chemical vapor deposition (LP CVD). The back contact 308 is a multi-layered structure that includes a silver alloy 322 and doped indium-tin-oxide 320.

### Example 6

In this example, a similar process as in Example 4 is followed, except that, the semiconductor is hydrogenated amorphous silicon carbon. A carbon containing gas, such as methane, is introduced into the reactor during the a-Si deposition process to incorporate carbon into some or all of the amorphous silicon layers.

### Example 7

In this example, a similar process as in Example 4 is followed. The semiconductor, however, is copper-indium-gallium-diselenide (CuInₓGa₁₋ₓSe₂). Copper is deposited onto the back contact 308 while the substrate is at about 275° C. Gallium is then deposited onto the deposited copper. Indium is deposited in the presence of a selenium flux onto the deposited gallium while the substrate is at about 275° C. Copper is then deposited onto the indium in the presence of a selenium flux while the substrate is at about 275° C., followed by deposition of gallium and then indium in the presence of a selenium flux onto the deposited gallium while the substrate is at about 275° C. The structure is then heated in the presence of a selenium flux to a temperature substantially higher than about 275° C.

### Example 8

In this example, a CdTe/CdS photovoltaic module is made as follows. After the glass substrate 302 is cleaned according to the method disclosed in Example 4, an n-type CdS film layer is deposited by vacuum evaporation at a substrate temperature of about 350° C. A p-type CdTe layer is formed by vacuum evaporation at a substrate temperature 350° C. The p-type CdTe layer is dipped in a methanol solution containing copper chloride (CuCl₂) or a CH₃OH solution containing CuCl₂ and CdCl₂. It is then dried by natural drying and annealed at 400° C. for 15 minutes in an N₂+O₂ (4:1) atmosphere. A surface of the CdTe layer is etched using a K₂Cr₂O₇+H₂SO₄+H₂O solution. Cu (10 nm)/Au (100 nm) is then deposited by vacuum evaporation and then annealed at 150° C. for about three hours.

Exemplary embodiments of the present invention have been presented. The invention is not limited to these examples. These examples are presented herein for purposes of illustration, and not limitation. Alternatives (including equivalents, extensions, variations, deviations, etc., of those described herein) will be apparent to persons skilled in the relevant art(s) based on the teachings contained herein. Such alternatives fall within the scope and spirit of the invention.

All publications, patents and patent applications mentioned in this specification are indicative of the level of skill of those skilled in the art to which this invention pertains, and are herein incorporated by reference to the same extent as if each individual publication, patent or patent application was specifically and individually indicated to be incorporated by reference.

What is claimed is:

1. A method of drying a glass substrate for use in a photovoltaic module, comprising,
(a) providing a glass substrate;
(b) heating the glass substrate;
(c) introducing a volatile organosilicon compound to the glass substrate, wherein water absorbed onto the glass substrate reacts with the compound to produce a reaction product; and
(d) removing the reaction product from the glass substrate.

2. The method of claim 1, wherein the introducing comprises introducing a volatile hydrolizable organosilicon compound.

3. The method of claim 2, wherein the introducing comprises introducing a volatile hydrolizable organosilicon compound selected from the class of organosilicon compounds RₐSiX_{b}, where a and b are between 1 to 3 with a+b=4, R selected from CH₃, C₂H₅, and C₆H₅, and X is Cl or Br.

4. The method of claim 2, wherein the introducing comprises introducing (CH₃)₃SiX, or (C₂H₅)₃SiX, where X is Cl or Br.

5. The method of claim 2, wherein the introducing comprises introducing trimethylchlorosilane.

6. The method of claim 1, wherein introducing comprises introducing a volatile organosilicon compound at a pressure in the range of about −30 psi to about 30 psi.

7. The method of claim 1, wherein the heating is to a temperature in the range of about 100° Celsius to about 450° Celsius.

8. The method of claim 1, wherein the heating occurs prior to the introduction of the volatile organosilicon compound.

9. A method of drying a glass substrate for use in a photovoltaic module, comprising,
(a) providing a glass substrate in a chamber;
(b) evacuating the chamber to a pressure of about −40 psi to about −10 psi;
(c) heating the glass substrate to a temperature of about 100° Celsius to about 450° Celsius;
(d) introducing a volatile organosilicon compound to the glass substrate at a pressure of about −30 psi to about 30 psi, wherein water absorbed onto the glass substrate reacts with the compound to produce a reaction product; and
(e) removing the reaction product from the glass substrate.

10. The method of claim 9, wherein the introducing comprises introducing a volatile hydrolizable organosilicon compound selected from the class of organosilicon compounds RₐSiX_{b}, where a and b are between 1 to 3 with a+b=4, R selected from CH₃, C₂H₅, and C₆H₅, and X is Cl or Br.

11. The method of claim 9, wherein the introducing comprises introducing trimethylchlorosilane.

12. The method of claim 9, wherein,
the evacuating is to a pressure of about −30 psi;
the heating is to a temperature of about 400° C.; and
the introducing is at a pressure of about 20 psi.

13. A glass substrate for use in a photovoltaic module prepared by the method of claim 1.

14. A glass substrate for use in a photovoltaic module prepared by the method of claim 9.

15. A method of preparing a photovoltaic module, comprising,
(a) providing a glass substrate;
(b) heating the glass substrate;
(c) introducing a volatile organosilicon compound to the glass substrate, wherein water absorbed onto the glass substrate reacts with the compound to produce a reaction product;
(d) removing the reaction product from the glass substrate;
(e) disposing a front contact electrode on the glass substrate;
(f) disposing a photovoltaic module semiconductor on the front contact;
(g) disposing a back contact electrode on the photovoltaic module semiconductor; and
(h) encapsulating the photovoltaic module.

16. The method of claim 15, wherein the introducing comprises introducing a volatile hydrolizable organosilicon compound selected from the class of organosilicon compounds RₐSiX_{b}, where a and b are between 1 to 3 with a+b=4, R selected from CH₃, C₂H₅, and C₆H₅, and X is Cl or Br.

17. The method of claim 15, wherein the introducing comprises introducing trimethylchlorosilane.

18. The method of claim 15, wherein introducing comprises introducing a volatile organosilicon compound at a pressure in the range of about −30 psi to about 30 psi, and the heating is to a temperature in the range of about 100° Celsius to about 450° Celsius.

19. The method of claim 15, wherein the disposing a photovoltaic module semiconductor comprises disposing a doped, hydrogenated amorphous silicon, hydrogenated amorphous silicon carbon, hydrogenated amorphous silicon germanium, CdTe or CIGS semiconductor.

20. A method of preparing a photovoltaic module, comprising,
(a) providing a glass substrate in a chamber;
(b) evacuating the chamber to a pressure of about −40 psi to about −10 psi;
(c) heating the glass substrate to a temperature of about 100° Celsius to about 450° Celsius;
(d) introducing a volatile organosilicon compound to the glass substrate at a pressure of about −30 psi to about 30 psi, wherein water absorbed onto the glass substrate reacts with the compound to produce a reaction product;
(e) removing the reaction product from the glass substrate;
(f) disposing a front contact electrode on the glass substrate;
(g) disposing a photovoltaic module semiconductor on the front contact;
(h) disposing a back contact electrode on the photovoltaic module semiconductor;
(i) performing laser scribings to interconnect the front contact electrode, the photovoltaic semiconductor and the back contact electrode.
(j) encapsulating the photovoltaic module.

21. The method of claim 20, wherein the introducing comprises introducing a volatile hydrolizable organosilicon compound selected from the class of organosilicon compounds RₐSiX_{b}, where a and b are between 1 to 3 with a+b=4, R selected from CH₃, C₂H₅, and C₆H₅, and X is Cl or Br.

22. The method of claim 20, wherein the disposing a photovoltaic module semiconductor comprises disposing a doped, hydrogenated amorphous silicon, hydrogenated amorphous silicon carbon, hydrogenated amorphous silicon germanium, CdTe or CIGS semiconductor.

23. The method of claim 20, wherein the disposing a front contact electrode comprises disposing a material selected from the group consisting of, tin oxide, indium-tin oxide, zinc oxide, and cadmium stannate.

24. The method of claim 20, wherein the disposing a back contact electrode comprises disposing a doped material selected from the group consisting of, tin oxide, zinc oxide, indium-tin-oxide and cadmium stannate.

25. The method of claim 20, wherein,
the evacuating is to a pressure of about −30 psi;
the heating is to a temperature of about 400° C.; and
the introducing is at a pressure of about 20 psi.

26. A photovoltaic module prepared by the method of claim 20.
